(19) United States
(12) Patent Application Publication
(10) Pub. No.: US 2025/0107209 A1
(43) Pub. Date: Mar. 27, 2025

(54) MATERIAL LAYER CONTAINING MOLYBDENUM TO PROTECT GATE DIELECTRIC

(71) Applicant: Intel Corporation, Santa Clara, CA (US)

(72) Inventors: Yoon Jung Chang, Hillsboro, OR (US); Zafrullah Jagoo, Aloha, OR (US); Sridhar Govindaraju, Portland, OR (US)

(73) Assignee: Intel Corporation, Santa Clara, CA (US)

(21) Appl. No.: 18/473,618

(22) Filed: Sep. 25, 2023

(51) Int. Cl. H01L 29/49; H01L 21/8238; H01L 27/092; H01L 29/06; H01L 29/423; H01L 29/66; H01L 29/775; H01L 29/78; H01L 29/786

(52) U.S. Cl. CPC H10D 64/665; H10D 30/014; H10D 30/024; H10D 30/43; H10D 30/6211; H10D 30/6735; H10D 30/6757; H10D 62/121; H10D 64/017; H10D 84/017; H10D 84/0193; H10D 84/038; H10D 84/853

(57) ABSTRACT

Techniques are provided to form an integrated circuit having a gate electrode that includes at least one layer containing molybdenum. A transistor includes a gate structure having a gate electrode on a gate dielectric. The gate structure extends around a fin or any number of nanowires (or nanoribbons or nanosheets) of semiconductor material. The gate electrode includes one or more conductive layers on the gate dielectric with at least one of those conductive layers containing molybdenum (e.g., molybdenum nitride). The conductive layer having molybdenum may be used during the formation of the gate dielectric (e.g., during an annealing process), thus resulting in a higher quality gate dielectric.

### BACKGROUND

As integrated circuits continue to scale downward in size, a number of challenges arise. For instance, reducing the size of memory and logic cells within the interconnect structure is becoming increasingly more difficult, as is reducing device spacing at the device layer. Maintaining a certain level of quality among the various transistor elements can be a challenge due to the number of different fabrication processes they may be subjected to. Accordingly, there remain a number of non-trivial challenges with respect to forming such high-density semiconductor devices.

### BRIEF DESCRIPTION OF THE DRAWINGS

FIGS. 1A and 1B are different cross-sectional views of an integrated circuit that includes gate structures which include at least one layer having molybdenum, in accordance with an embodiment of the present disclosure.

FIGS. 2A and 2B are cross-sectional views that illustrate one stage in an example process for forming an integrated circuit configured with gate structures which include at least one layer having molybdenum, in accordance with an embodiment of the present disclosure.

FIGS. 3A and 3B are cross-sectional views that illustrate another stage in the example process for forming an integrated circuit configured with gate structures which include at least one layer having molybdenum, in accordance with an embodiment of the present disclosure.

FIGS. 4A and 4B are cross-sectional views that illustrate another stage in the example process for forming an integrated circuit configured with gate structures which include at least one layer having molybdenum, in accordance with an embodiment of the present disclosure.

FIGS. 5A and 5B are cross-sectional views that illustrate another stage in the example process for forming an integrated circuit configured with gate structures which include at least one layer having molybdenum, in accordance with an embodiment of the present disclosure.

FIGS. 6A and 6B are cross-sectional views that illustrate another stage in the example process for forming an integrated circuit configured with gate structures which include at least one layer having molybdenum, in accordance with an embodiment of the present disclosure.

FIGS. 7A and 7B are cross-sectional views that illustrate another stage in the example process for forming an integrated circuit configured with gate structures which include at least one layer having molybdenum, in accordance with an embodiment of the present disclosure.

FIGS. 8A and 8B are cross-sectional views that illustrate another stage in the example process for forming an integrated circuit configured with gate structures which include at least one layer having molybdenum, in accordance with an embodiment of the present disclosure.

FIGS. 9A and 9B are cross-sectional views that illustrate another stage in the example process for forming an integrated circuit configured with gate structures which include at least one layer having molybdenum, in accordance with an embodiment of the present disclosure.

FIGS. 10A and 10B are cross-sectional views that illustrate another stage in the example process for forming an integrated circuit configured with gate structures which include at least one layer having molybdenum, in accordance with an embodiment of the present disclosure.

FIGS. 11A and 11B are cross-sectional views that illustrate another stage in the example process for forming an integrated circuit configured with gate structures which include at least one layer having molybdenum, in accordance with an embodiment of the present disclosure.

FIGS. 12A and 12B are cross-sectional views that illustrate another stage in the example process for forming an integrated circuit configured with gate structures which include at least one layer having molybdenum, in accordance with an embodiment of the present disclosure.

FIGS. 13A and 13B are cross-sectional views that illustrate another stage in the example process for forming an integrated circuit configured with gate structures which include at least one layer having molybdenum, in accordance with an embodiment of the present disclosure.

FIGS. 14A and 14B are cross-sectional views that illustrate another stage in the example process for forming an integrated circuit configured with gate structures which include at least one layer having molybdenum, in accordance with an embodiment of the present disclosure.

FIGS. 15A and 15B are cross-sectional views that illustrate another stage in the example process for forming an integrated circuit configured with gate structures which include at least one layer having molybdenum, in accordance with an embodiment of the present disclosure.

FIG. 16 is a cross-sectional view of another example semiconductor device configured with gate structures which include at least one layer having molybdenum, in accordance with an embodiment of the present disclosure.

FIG. 17 illustrates a cross-sectional view of a chip package containing one or more semiconductor dies, in accordance with some embodiments of the present disclosure.

FIG. 18 is a flowchart of a fabrication process for an integrated circuit that includes gate structures which include at least one layer having molybdenum, in accordance with an embodiment of the present disclosure.

FIG. 19 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form an integrated circuit having a gate electrode that includes at least one layer containing molybdenum. The techniques can be used in any number of integrated circuit applications and are particularly useful with respect to logic and memory cells, such as those cells that use finFETs or gate-all-around transistors (e.g., ribbonFETs and nanowire FETs). In one such example, a FET (field effect transistor) includes a gate structure having a gate electrode on a gate dielectric. The gate structure extends around a fin or any number of nanowires (or nanoribbons or nanosheets, as the case may be) of semiconductor material. The semiconductor material may extend in a first direction between source and drain regions while the gate structure extends over the semiconductor material in a second direction substantially orthogonal to the first direction. The gate electrode includes one or more conductive layers on the gate dielectric with at least one of those conductive layers having molybdenum and nitrogen (e.g., molybdenum nitride). The conductive layer having molybdenum may be used during the formation of the gate dielectric to protect the gate dielectric during an annealing step, thus resulting in a higher quality gate dielectric. Numerous variations and embodiments will be apparent in light of this disclosure.

### General Overview

As previously noted above, there remain a number of non-trivial challenges with respect to integrated circuit fabrication. In more detail, the gate dielectric of a FET is an important element that separates the gate electrode from the semiconductor material of the transistor. Any degradation to the quality of the gate dielectric can have negative effects on the performance of the transistor. A given gate dielectric may be subjected to an annealing process to strengthen the integrity of the gate dielectric and drive certain desired elements into the gate dielectric. Additional material layers may be deposited on the gate dielectric prior to the anneal, which may provide a degree of protection to the gate dielectric during the annealing process. However, the deposition of these additional layers can actually damage the underlying gate dielectric and cause it to be partially removed during later fabrication. For example, a layer of titanium nitride is often deposited on the gate dielectric prior to the annealing operation. But depositing titanium nitride uses a chlorine-based precursor (TiCl₄) at a high temperature, which can produce byproducts that attack the gate dielectric and make it more susceptible to being removed during later gate patterning processes.

Thus, and in accordance with an embodiment of the present disclosure, techniques are provided herein to protect the gate dielectric during device fabrication. The techniques may be used, for instance, to replace a layer of titanium nitride (TiN) or other layer that may cause damage to the underlying gate dielectric. Such potentially damaging layers (e.g., TiN) may be replaced with a layer containing molybdenum. For example, the layer containing molybdenum may be deposited over the gate dielectric to effectively protect the gate dielectric during an annealing process. The layer containing molybdenum may then remain over the gate dielectric as one of the conductive layers within the gate electrode. According to some embodiments, the gate dielectric includes at least one high-k dielectric layer (e.g., materials with a dielectric constant higher than that of silicon dioxide or higher than 3.9), such as hafnium dioxide. The conductive layer used on the gate dielectric may include, for example, molybdenum nitride. During the formation of the gate electrode, additional conductive layers may be formed on the layer of molybdenum nitride to create workfunction metal layers as well as a metal fill on the workfunction metal layers. The material type and relative thickness of the various workfunction metal layers may vary depending on whether the transistor is n-type or p-type and on the desired threshold voltage of the transistor. In general, the device's threshold voltage decreases as the thickness of a given workfunction layer increases. In some embodiments, a p-type FET includes a plurality of workfunction layers having a material layer with molybdenum nitride, a material layer with tantalum nitride, and a material layer with titanium nitride. In some embodiments, an n-type FET includes a plurality of workfunction layers having a material layer with molybdenum nitride, and a material layer with tantalum nitride (e.g., no titanium nitride). In some embodiments, the layer containing molybdenum nitride is removed for some n-type FET devices, such that those n-type FET devices do not include a workfunction layer having molybdenum, yet still reap the benefits of an improved gate dielectric. An example fill metal on the workfunction layer(s) is tungsten. The quality of the gate dielectric may be determined using measurements of parameters such as gate leakage, threshold voltage, and max voltage before transistor breakdown (VMAX).

According to an embodiment, a method of forming an integrated circuit includes forming a fin comprising one or more semiconductor layers, the fin extending in a first direction over a substrate; forming a sacrificial gate, the sacrificial gate extending in a second direction over the fin, the second direction being different from the first direction; removing an exposed portion of the fin adjacent to the sacrificial gate to form a recess through the fin; forming a source or drain region from ends of the one or more semiconductor layers and within the recess; removing the sacrificial gate from around the fin; forming one or more dielectric layers on the one or more semiconductor layers of the fin; forming a conductive layer on the one or more dielectric layers, wherein the conductive layer comprises molybdenum and nitrogen; after forming the conductive layer, annealing the one or more dielectric layers; and forming one or more additional conductive layers over the conductive layer.

According to another embodiment, an integrated circuit includes a semiconductor region extending from a source or drain region in a first direction, and a gate structure extending over the semiconductor region in a second direction different from the first direction. The gate structure includes one or more dielectric layers on the semiconductor region and one or more conductive layers on the one or more dielectric layers. The one or more conductive layers includes a conductive layer comprising molybdenum and nitrogen. The source or drain region may include, for instance, silicon, germanium, or silicon germanium (SiGe) doped with n-type dopants.

According to another embodiment, an electronic device includes a chip package having one or more dies. At least one of the one or more dies includes a semiconductor device having a semiconductor region extending from a source or drain region in a first direction and a gate structure extending over the semiconductor region in a second direction different from the first direction. The gate structure includes one or more dielectric layers on the semiconductor region and one or more conductive layers on the one or more dielectric layers. The one or more conductive layers includes a conductive layer comprising molybdenum and nitrogen. The source or drain region may include, for instance, silicon, germanium, or SiGe doped with n-type dopants.

The techniques can be used with any type of planar or non-planar transistors, including finFETs (sometimes called double-gate transistors, or tri-gate transistors), or nanowire and nanoribbon transistors (sometimes called gate-all-around transistors), or forksheet transistors, to name a few examples. More generally, the techniques described herein may benefit any transistor architecture having a gate dielectric layer that is subjected to relatively high temperature anneals (e.g., 500° C. to 700° C.). The source and drain regions can be, for example, doped portions of a given fin or substrate, or epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a replacement metal gate, or RMG, process), or any other gate formation process. Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the presence of a metal layer having molybdenum as part of the gate electrode of a transistor. In some embodiments, the layer having molybdenum also includes nitrogen and is arranged between a gate dielectric and one or more other metal layers that are part of the gate electrode. The layer having molybdenum may be observed directly on the gate dielectric.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element (s) or feature (s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the material has an element that is not in the other material.

### Architecture

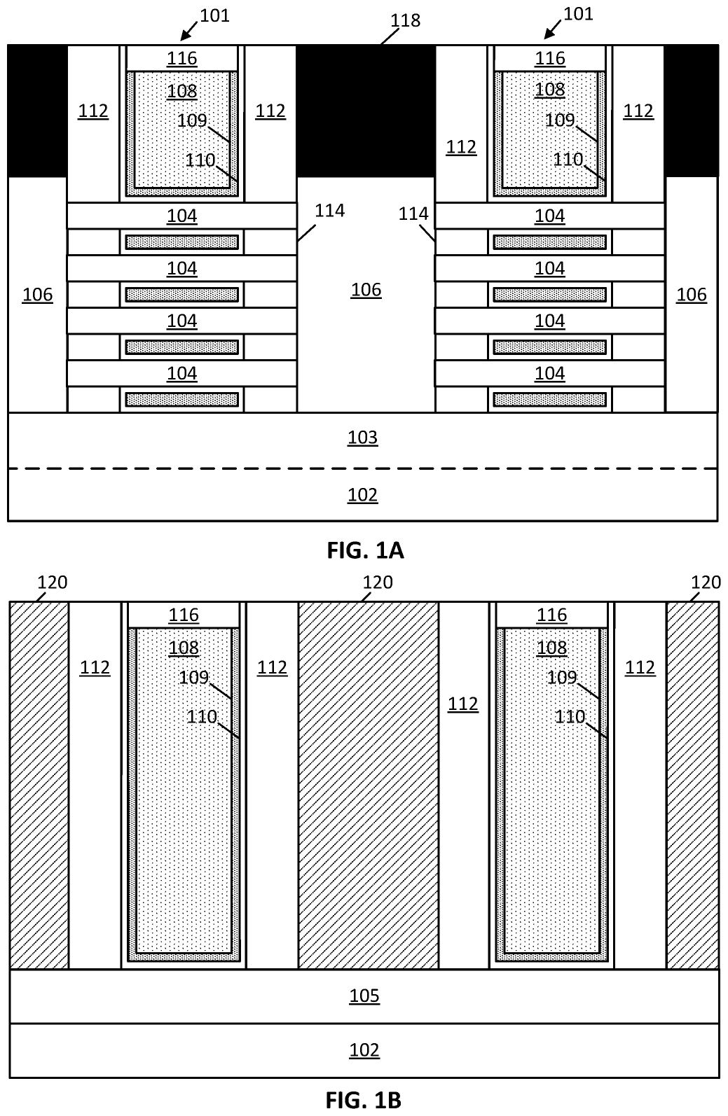

FIG. 1A is a cross-section view taken through various semiconductor devices 101 along a ‘fin’ direction that illustrates the semiconductor bodies extending between source or drain regions of each semiconductor device 101, in accordance with an embodiment of the present disclosure. FIG. 1B illustrates a cross-section view taken parallel to the cross-section from FIG. 1A and into the page (or out of the page, as the case may be), such that it is away from the semiconductor bodies of the transistors but still crosses the gate structures extending over the semiconductor bodies. Each of the semiconductor devices may be, for instance, non-planar metal oxide semiconductor (MOS) transistors, such as tri-gate (e.g., finFET) or gate-all-around (GAA) transistors, although other transistor topologies and types could also benefit from the techniques provided herein. The examples herein illustrate semiconductor devices with a GAA structure (e.g., having nanoribbons, nanowires, or nanosheets that extend between source and drain regions). Other examples may have a forksheet structure having a p-type device and an n-type device separated by a dielectric spine or structure.

The semiconductor material used in each of the semiconductor devices may be formed from a semiconductor substrate 102. Substrate 102 can be, for example, a bulk substrate including group IV semiconductor material (such as silicon, germanium, or SiGe), group III-V semiconductor material (such as gallium arsenide, indium gallium arsenide, or indium phosphide), and/or any other suitable material upon which transistors can be formed. Alternatively, the substrate can be a semiconductor-on-insulator substrate having a desired semiconductor layer over a buried insulator layer (e.g., silicon over silicon dioxide). Alternatively, the substrate can be a multilayer substrate or superlattice suitable for forming nanowires or nanoribbons (e.g., alternating layers of silicon and SiGe, or alternating layers indium gallium arsenide and indium phosphide). Any number of substrates can be used. In some embodiments, substrate 102 is removed and replaced with one or more backside interconnect layers to form backside signal and power routing.

The one or more semiconductor regions of the devices may include fins that can be, for example, native to substrate 102 (formed from the substrate itself), such as silicon fins etched from a bulk silicon substrate. Alternatively, the fins can be formed of material deposited onto substrate 102. In one such example case, a blanket layer of SiGe can be deposited onto a silicon substrate, and then patterned and etched to form a plurality of SiGe fins extending from that substrate. In still other embodiments, the fins include alternating layers of material (e.g., alternating layers of silicon and SiGe) that facilitates forming of nanowires and nanoribbons and nanosheets during a gate forming process where one type of the alternating layers is selectively etched away so as to liberate the other type of alternating layers within the channel region, so that a gate-all-around process or a forksheet gate process can then be carried out. Again, the alternating layers can be blanket deposited and then etched into fins or deposited into fin-shaped trenches, in some examples.

According to some embodiments, semiconductor devices 101 further include a subfin region 103 that extends in the first direction beneath semiconductor devices 101. According to some embodiments, subfin region 103 is a portion of the corresponding semiconductor fin that remains after formation of the various transistors and may be formed from substrate 102. Accordingly, subfin region 103 may include the same semiconductor material as substrate 102 (or any semiconductor material in situations where substrate 102 is removed).

Each semiconductor device 101 includes one or more semiconductor regions (also called channel regions), such as one or more nanoribbons 104 extending between epitaxial source or drain regions 106 in the first direction. A gate structure extends over the one or more semiconductor regions (e.g., nanoribbons 104) of a given semiconductor device 101 in a second direction (e.g., into and out of the page) to form the transistor gate. Subfin region 103 may extend along the first direction beneath one or more nanoribbons 104 and be flanked by a dielectric fill 105 in areas not beneath one or more nanoribbons 104, as shown in FIG. 1B. Accordingly, dielectric fill 105 may act as shallow trench isolation (STI) between adjacent subfins along the second direction (e.g., into and out of the page).

Any of source or drain regions 106 may act as either a source region or a drain region, depending on the application and dopant profile. Any semiconductor materials suitable for source and drain regions can be used (e.g., group IV and group III-V semiconductor materials) for any of the illustrated source or drains regions 106. In any such cases, the composition and doping of source or drain regions 106 may be the same or different, depending on the polarity of the transistors. For example, any semiconductor devices that are p-channel transistors have a high concentration of p-type dopants in the associated source or drain regions 106, and any semiconductor devices that are n-channel transistors have a high concentration of n-type dopants in the associated source or drain regions 106. Example p-type dopants include boron and example n-type dopants include phosphorous. Any number of source and drain configurations and materials can be used. In some examples, n-type source or drain regions include silicon doped with phosphorous and p-type source or drain regions include silicon germanium doped with boron.

The gate structure may include a gate electrode that is made up of a conductive fill 108 and one or more metal workfunction layers 109, according to some embodiments. The gate structures also include a gate dielectric 110 that may represent any number of dielectric layers. Conductive fill 108 may include any sufficiently conductive material such as a metal, metal alloy, or doped polysilicon. In some examples, conductive fill 108 includes tungsten (W), although other metals or conductive materials may be used, such as aluminum (Al), ruthenium (Ru), cobalt (Co), or doped polysilicon. In some embodiments, one or both of semiconductor devices 101 are p-channel devices where one or more workfunction layers 109 includes a layer of molybdenum nitride (MoN). Other metal workfunction layers 109 of the p-channel devices can include tantalum nitride (TaN) and titanium nitride (TiN). In some embodiments, one or both of semiconductor devices 101 are n-channel devices where one or more workfunction layers 109 includes a layer of molybdenum nitride (MoN). Other metal workfunction layers 109 of the n-channel devices can include tantalum nitride (TaN). The MoN layer may be deposited on gate dielectric 110 prior to an annealing procedure and remain on gate dielectric 110 to act as one of the gate electrode workfunction metals, according to some embodiments.

Gate dielectric 110 may include any suitable gate dielectric material(s). In some embodiments, gate dielectric 110 includes a layer of native oxide material (e.g., silicon dioxide germanium dioxide, or SiGe oxide) on nanoribbons 104 or other semiconductor regions, and a layer of high-k dielectric material (e.g., hafnium oxide or aluminum oxide) on the native oxide. According to some embodiments, spacer structures 112 and inner spacers 114 are present along the sidewalls of the gate structures. Spacer structures 112 and inner spacers 114 may be any suitable dielectric material, such as silicon nitride, and provide separation between a given gate structure and the adjacent source or drain region 106. Inner spacers 114 may separate adjacent nanoribbons 104 from one another along a third direction (e.g., a vertical direction).

According to some embodiments, a dielectric cap layer 116 may be present over the gate electrodes within the gate trenches of semiconductor devices 101. A top surface of dielectric cap layer 116 may be substantially co-planar with a top surface of spacer structures 112. Dielectric cap layer 116 may include the same dielectric material as spacer structures 112, in some examples.

According to some embodiments, conductive contacts 118 are provided on source or drain regions 106 Conductive contacts 118 can include any suitable conductive material, such as tungsten, molybdenum, ruthenium, cobalt, or other metals. Conductive contacts 118 may be formed together such that they all include the same conductive material.

As shown in FIG. 1B, dielectric plugs 120 may be present within the source/drain trenches to separate source or drain regions 106 from other source or drain regions along the second direction (e.g., into and out of the page), according to some embodiments. Dielectric plugs 120 may be any suitable dielectric material, such as silicon dioxide, silicon oxynitride, or silicon oxycarbide.

### Fabrication Methodology

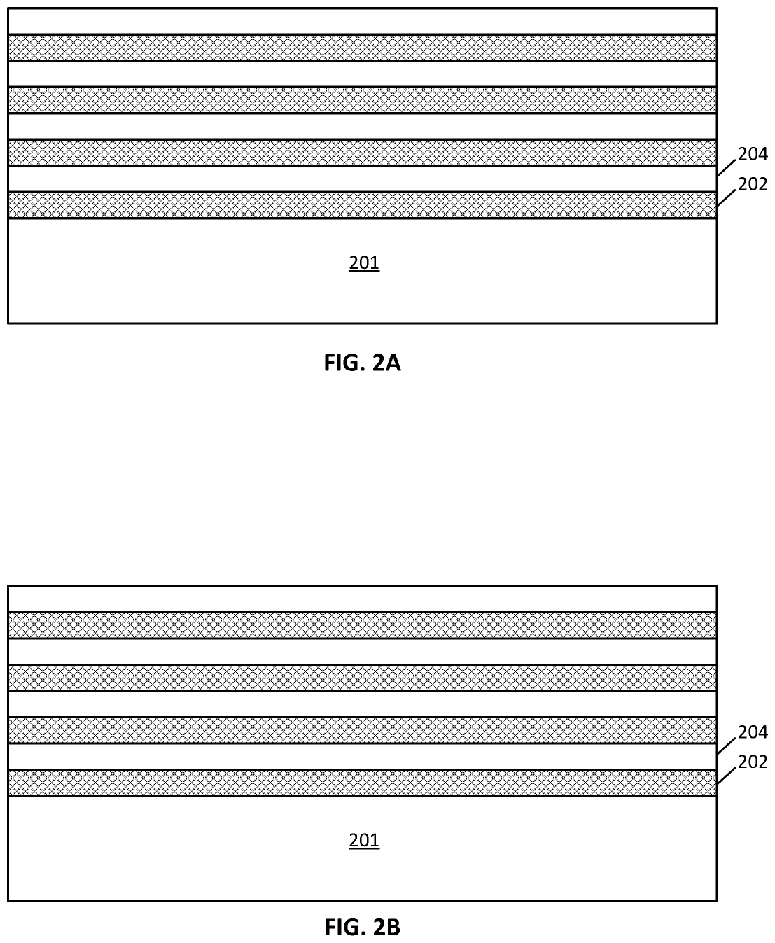

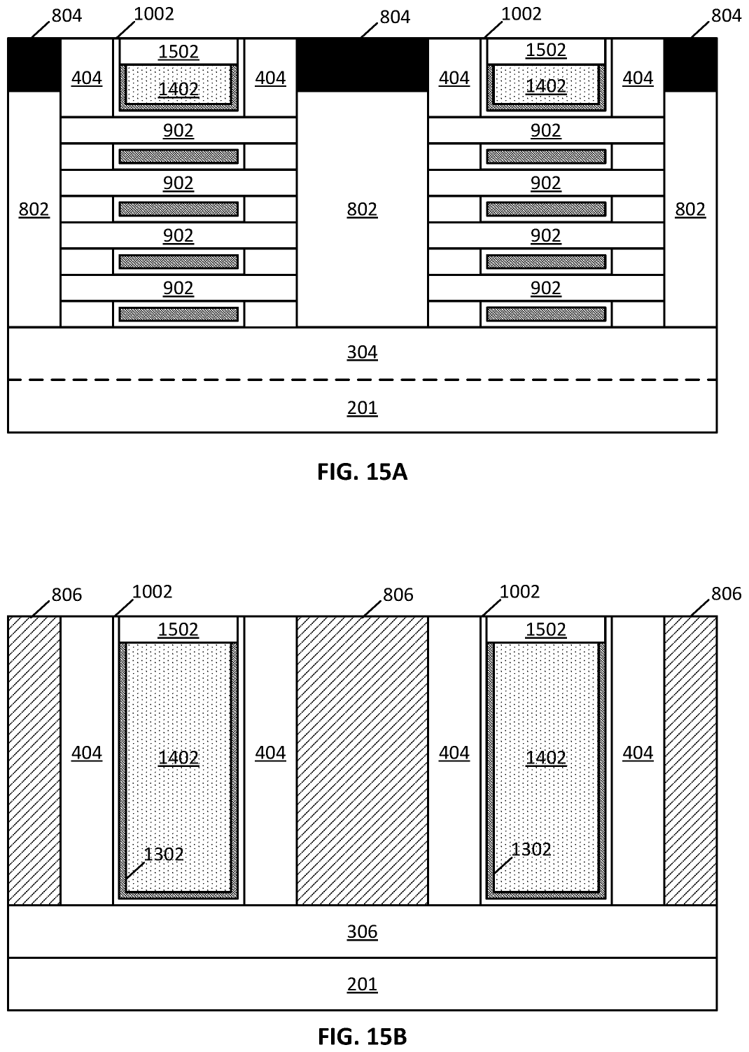

FIGS. 2A-15A and 2B-15B include cross-sectional views that collectively illustrate an example process for forming an integrated circuit configured with a molybdenum-containing workfunction layer, in accordance with an embodiment of the present disclosure. FIGS. 2A-15A represent a similar cross-sectional view as that of FIG. 1A across a series of semiconductor devices, while FIGS. 2B-15B represent a similar cross-sectional view as that of FIG. 1B parallel to the view in FIGS. 2A-15A and away from the semiconductor devices. Each set of figures sharing the same letter shows an example structure that results from the process flow up to that point in time, so the depicted structure evolves as the process flow continues, culminating in the structure shown in FIGS. 15A-15B, which is similar to the structure shown in FIGS. 1A and 1B. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but other materials and process parameters may be used as well, as will be appreciated in light of this disclosure.

FIGS. 2A and 2B each illustrates a cross-sectional view taken through a substrate 201 having a series of material layers formed over a substrate, according to an embodiment of the present disclosure. Alternating material layers may be deposited over substrate 201 including sacrificial layers 202 alternating with semiconductor layers 204. The alternating layers are used to form GAA transistor structures. Any number of alternating sacrificial layers 202 and semiconductor layers 204 may be deposited over substrate 201. Substrate 201 may be substantially similar to substrate 102 described above.

According to some embodiments, semiconductor layers 204 have a different material composition than sacrificial layers 202. In some embodiments, semiconductor layers 204 include a semiconductor material suitable for use as a nanoribbon such as silicon (Si), SiGe, germanium, or III-V materials like indium phosphide (InP) or gallium arsenide (GaAs). Sacrificial layers 202 include a material that can be selectively removed relative to semiconductor layers 204. In some examples, for instance, semiconductor layers 204 are silicon and sacrificial layers 202 are SiGe, or vice-versa. In some other examples where SiGe is used in each of semiconductor layers 204 and in sacrificial layers 202, the germanium concentration is different between semiconductor layers 204 and sacrificial layers 202, so as to allow for etch selectivity. For example, semiconductor layers 204 may include a higher germanium content compared to sacrificial layers 202.

While dimensions can vary from one example embodiment to the next, the thickness of each semiconductor layer 204 may be between about 5 nm and about 20 nm, in some examples. In some embodiments, the thickness of each semiconductor layer 204 is substantially the same (e.g., within 1-2 nm). The thickness of each of sacrificial layers 202 may be about the same as the thickness of each semiconductor layer 204 (e.g., about 5-20 nm). Each of semiconductor layers 204 and sacrificial layers 202 may be deposited using any material deposition technique, such as chemical vapor deposition (CVD), plasma-enhanced chemical vapor deposition (PECVD), physical vapor deposition (PVD), or atomic layer deposition (ALD), or epitaxial growth.

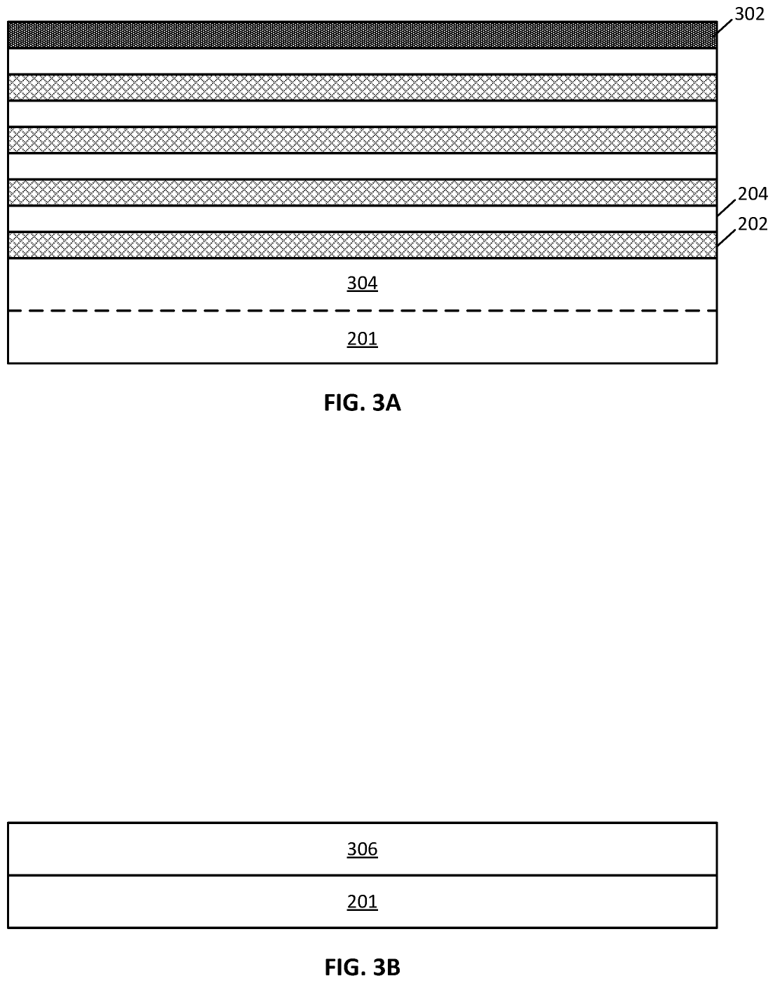

FIGS. 3A and 3B depict the cross-section views of the structure shown in FIGS. 2A and 2B, respectively, following the formation of a cap layer 302 and the subsequent formation of fins beneath cap layer 302, according to an embodiment. Cap layer 302 may be any suitable hard mask material such as a carbon hard mask (CHM) or silicon nitride. Cap layer 302 is patterned into rows to form corresponding rows of fins from the alternating layer stack of sacrificial layers 202 and semiconductor layers 204. Cap layer 302 extends along the top of each fin in a first direction, as seen in FIG. 3A.

According to some embodiments, an anisotropic etching process through the layer stack continues into at least a portion of substrate 201. Portions of substrate 201 beneath the fins are not etched and yield subfin regions 304 as illustrated in FIG. 3A. The etched portions of substrate 201 that are not under the fins may be filled with a dielectric fill 306 that acts as shallow trench isolation (STI) between adjacent fins as illustrated in FIG. 3B. Dielectric fill 306 may be any suitable dielectric material such as silicon dioxide. Subfin regions 304 represent remaining portions of substrate 201 flanked by dielectric fill 306, according to some embodiments.

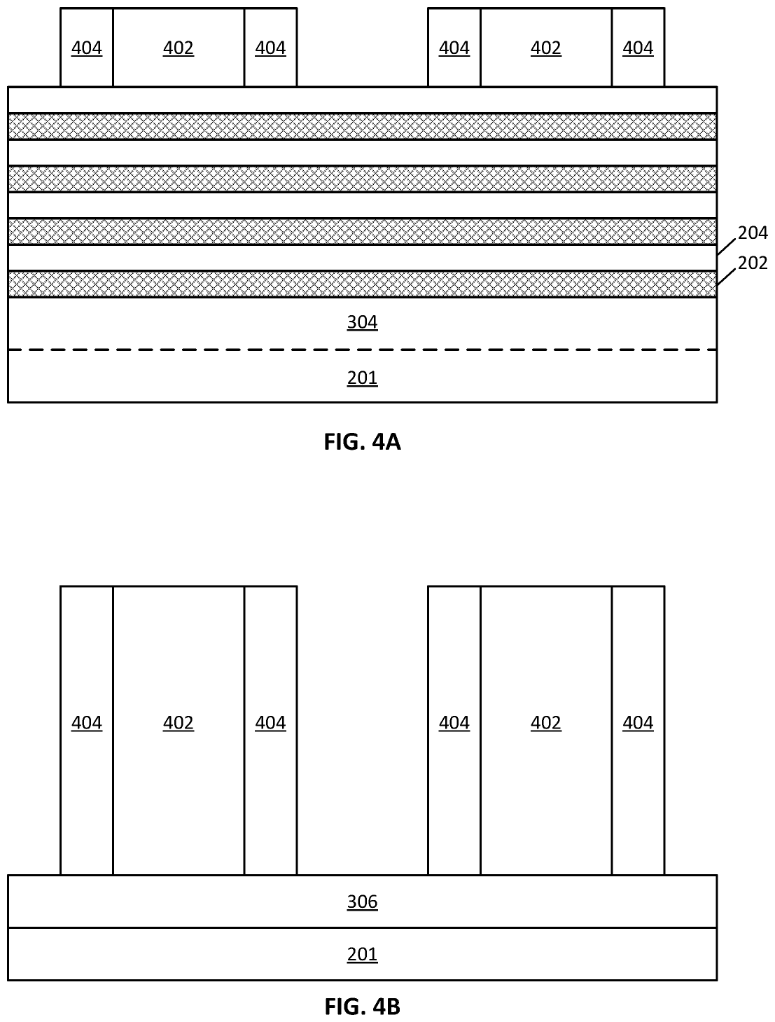

FIGS. 4A and 4B depict cross-section views of the structures shown in FIGS. 3A and 3B following the formation of sacrificial gates 402 and spacer structures 404, according to some embodiments. A gate masking layer may first be patterned in strips that extend orthogonally across each of the fins (e.g., in a second direction) in order to form corresponding sacrificial gates 402 in strips beneath the gate masking layers. Afterwards, the gate masking layers may be removed or may remain as a cap layer above each sacrificial gate 402. According to some embodiments, the sacrificial gate material is removed in all areas not protected by the gate masking layers. Sacrificial gate 402 may be any suitable material that can be selectively removed without damaging the semiconductor material of the fins. In some examples, sacrificial gate 402 includes polysilicon.

According to some embodiments, spacer structures 404 are formed along the sidewalls of sacrificial gates 402. Spacer structures 404 may be conformally deposited (e.g., CVD or ALD)_and then etched back or otherwise removed (e.g., via anisotropic or directional etch) from horizontal surfaces, such that spacer structures 404 remain mostly only on sidewalls of any exposed structures. The width of spacer structures 404 (along the first direction) may vary from one example to the next, but in some cases is in the range of 3 nm to 20 nm. According to some embodiments, spacer structures 404 may be any suitable dielectric material, such as silicon nitride, silicon carbon nitride, or silicon oxycarbonitride. In one such embodiment, spacer structures 404 comprise a nitride and dielectric fill 306 comprises an oxide, so as to provide a degree of etch selectivity during final gate processing. Other etch selective dielectric schemes (e.g., oxide/carbide, carbide/nitride) can be used as well for spacer structures 404 and dielectric fill 306. In other embodiments, spacer structures 404 and dielectric fill 306 are compositionally the same or otherwise similar, where etch selectivity is not employed.

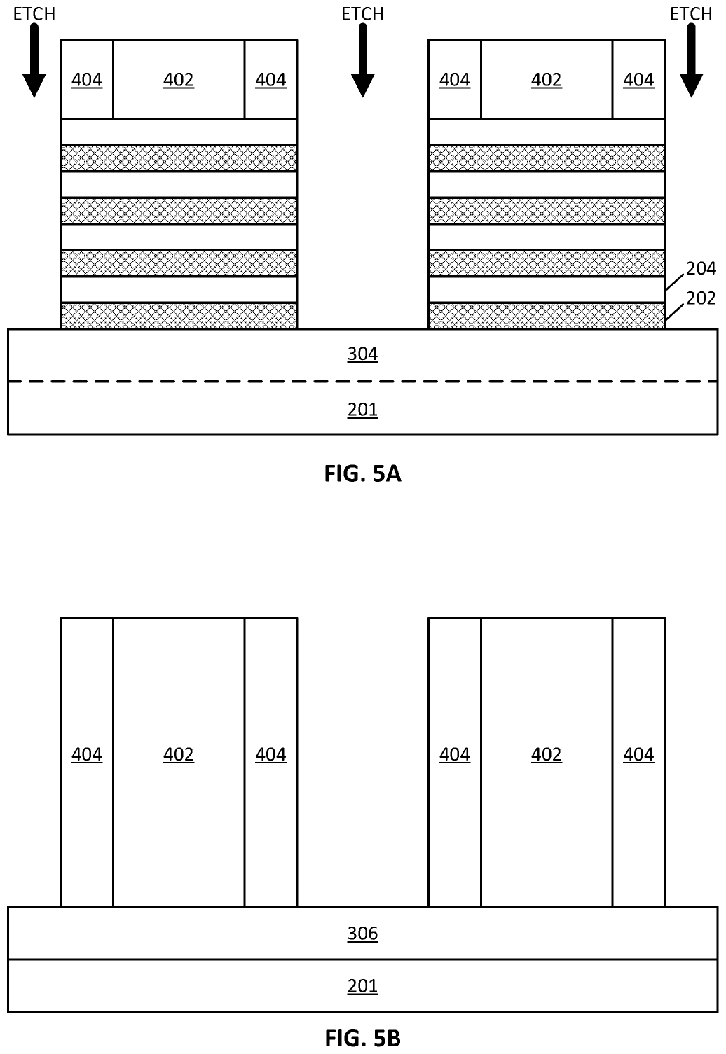

FIGS. 5A and 5B depict cross-section views of the structures shown in FIGS. 4A and 4B following the removal of exposed portions of the fins not protected by sacrificial gates 402 and spacer structures 404, according to some embodiments. The exposed fin portions may be removed using any anisotropic etching process, such as reactive ion etching (RIE) or other directional etch process. The removal of the exposed fin portions creates source or drain trenches that alternate with gate trenches (currently filled with sacrificial gates 402) along the first direction, according to some embodiments. In some embodiments, at least a portion of subfin regions 304 is also removed such that a top surface of subfin regions 304 is recessed below a top surface of dielectric fill 306. The recessed area above subfin regions 304 may be filled with one or more dielectric materials.

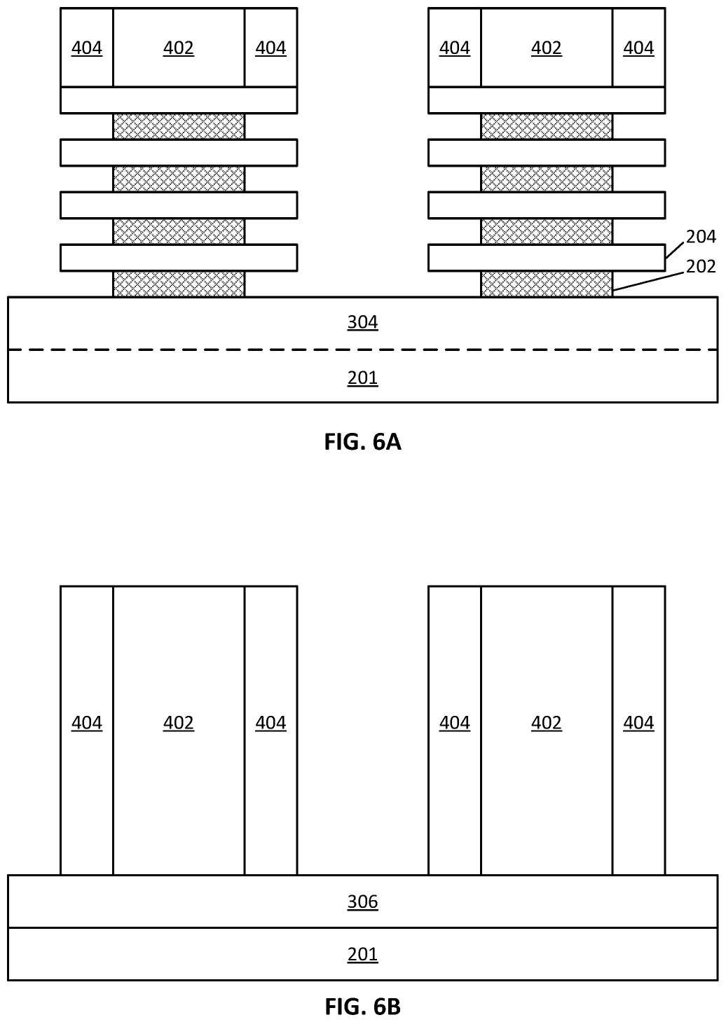

FIGS. 6A and 6B depict cross-section views of the structures shown in FIGS. 5A and 5B following the removal of portions of sacrificial layers 202, according to an embodiment of the present disclosure. An isotropic etching process may be used to selectively recess the exposed ends of each sacrificial layer 202 (e.g., while etching comparatively little of semiconductor layers 204).

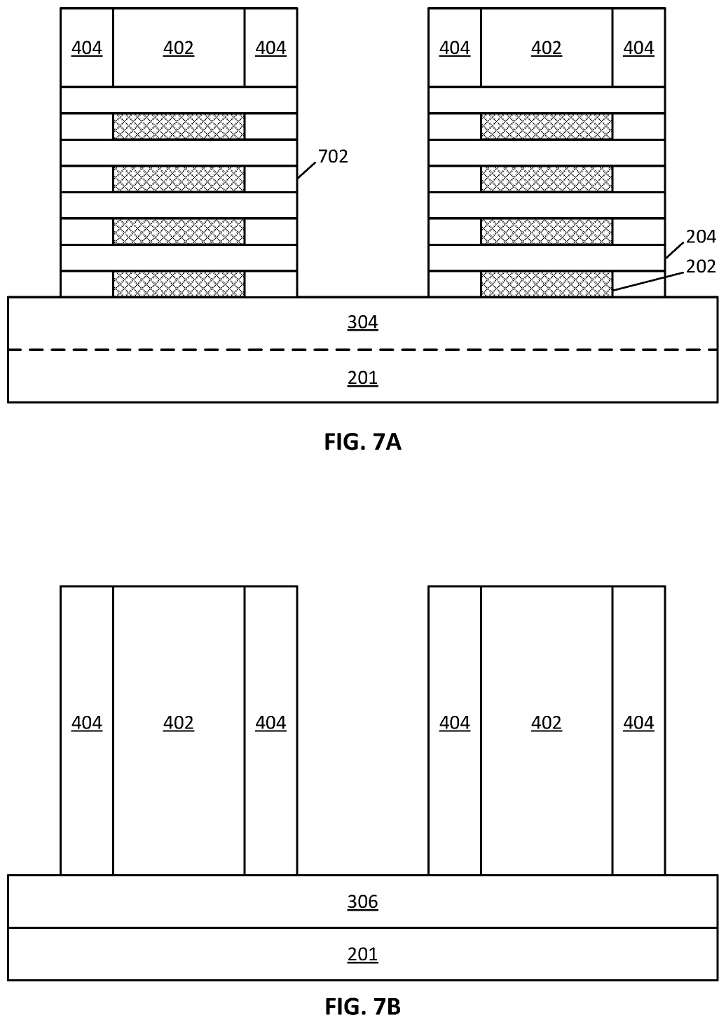

FIGS. 7A and 7B depict cross-section views of the structures shown in FIGS. 6A and 6B following the formation of internal spacers 702, according to an embodiment of the present disclosure. Internal spacers 702 may have a material composition that is similar to or the exact same as spacer structures 404. Accordingly, internal spacers 702 may be any suitable dielectric material that exhibits high etch selectively to semiconductor materials such as silicon and/or silicon germanium. Internal spacers 702 may be, for example, conformally deposited over the sides of the fin structure using a conformal deposition process like CVD or ALD and then etched back using an isotropic etching process to expose the ends of semiconductor layers 204. According to some embodiments, internal spacers 702 have a similar width (e.g., along the first direction) to spacer structures 404. Note that internal spacers 702 may be only formed around the ends of semiconductor layers 204 and not along other edges of the gate trench away from semiconductor layers 204 (as shown in FIG. 7B), according to some embodiments.

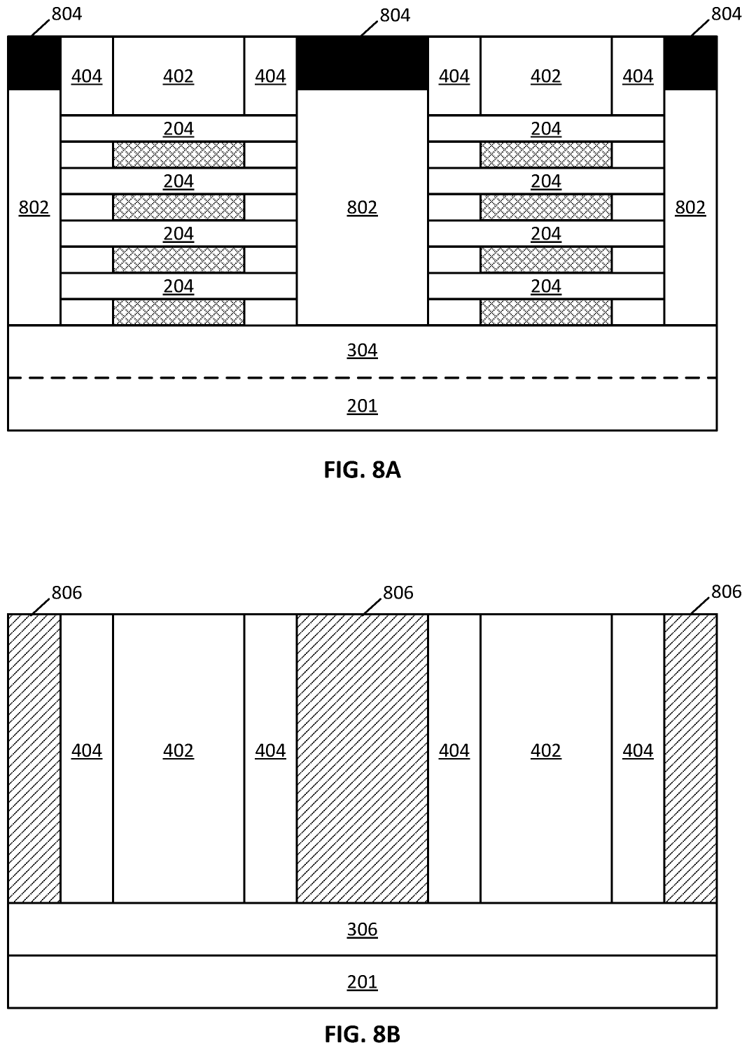

FIGS. 8A and 8B depict cross-section views of the structure shown in FIGS. 7A and 7B, respectively, following the formation of source or drain regions 802 within the source/drain trenches, according to some embodiments. Source or drain regions 802 may be formed in the areas that had been previously occupied by the exposed fins between spacer structures 404. According to some embodiments, source or drain regions 802 are epitaxially grown from the exposed semiconductor material at the ends of semiconductor layers 204. In some example embodiments, source or drain regions 802 are n-channel source or drain regions (e.g., epitaxial silicon with n-type dopants) or p-channel source or drain regions (e.g., epitaxial SiGe with p-type dopants). Contacts 804 may be formed over the top surfaces of source or drain regions 802. Contacts 804 may include any suitable conductive material, such as tungsten, cobalt, molybdenum, or ruthenium, for making electrical contact with the underlying source or drain regions 802. In some embodiments, the regions above source or drain regions 802 is filled with a dielectric that is replaced with contacts 804 after the replacement of sacrificial gates 402 with gate structures.

According to some embodiments, a dielectric fill 806 is provided between adjacent source or drain regions 802 along a given source/drain trench running in the second direction. In some examples, dielectric fill 806 occupies a remaining volume within the source/drain trench around and possible over portions of source or drain regions 802. Dielectric fill 806 may be any suitable dielectric material, such as silicon dioxide. In some examples, dielectric fill 806 extends up to and planar with a top surface of spacer structures 404 (e.g., following a polishing procedure).

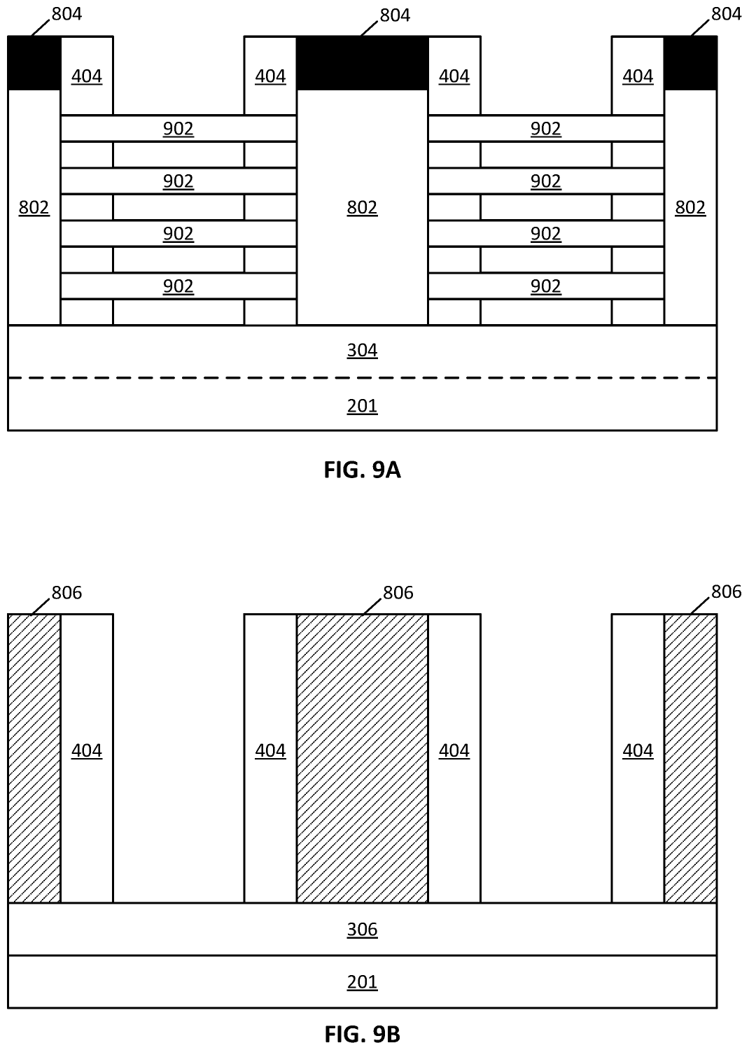

FIGS. 9A and 9B depict cross-section views of the structure shown in FIGS. 8A and 8B, respectively, following the removal of sacrificial gates 402 and sacrificial layers 202, according to some embodiments. In examples where gate masking layers are still present, they may be removed at this time. Once sacrificial gates 402 are removed, the fins extending between spacer structures 404 are exposed.

In the example where the fins include alternating semiconductor layers 202 and 204, sacrificial layers 202 are selectively removed to leave behind nanoribbons 902 that extend between corresponding source or drain regions 802. Each vertical set of nanoribbons 902 represents the semiconductor region (also called channel region) of a different semiconductor device. It should be understood that nanoribbons 902 may also be nanowires or nanosheets. Sacrificial gates 402 and sacrificial layers 202 may be removed using the same isotropic etching process or different isotropic etching processes.

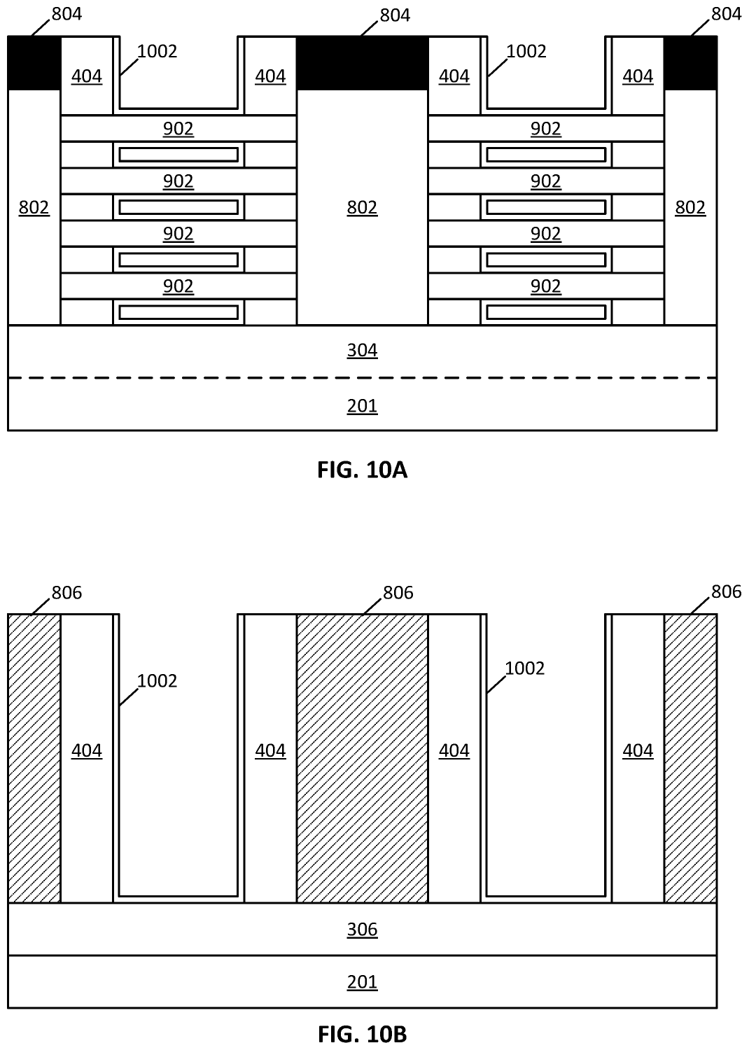

FIGS. 10A and 10B depict cross-section views of the structure shown in FIGS. 9A and 9B, respectively, following the formation of a gate dielectric 1002, according to some embodiments. Gate dielectric 1002 may be formed around nanoribbons 902 and along any exposed surfaces within the gate trenches, such as along sidewalls of spacer structures 404. Gate dielectric 1002 may include any suitable dielectric material (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, gate dielectric 1002 includes a layer of hafnium oxide with a thickness between about 1 nm and about 5 nm. In some embodiments, gate dielectric 1002 may include one or more silicates (e.g., titanium silicate, tungsten silicate, niobium silicate, and silicates of other transition metals). In some cases, gate dielectric 1002 includes a first layer on nanoribbons 902, and a second layer on the first layer. The first layer can be, for instance, an oxide of the semiconductor material of nanoribbons 902 (e.g., silicon dioxide) and the second layer can be a high-k dielectric material (e.g., hafnium oxide or aluminum oxide). Any excess gate dielectric may be removed from the top surface of structure, for instance, via a polishing process (e.g., chemical mechanical planarization, CMP).

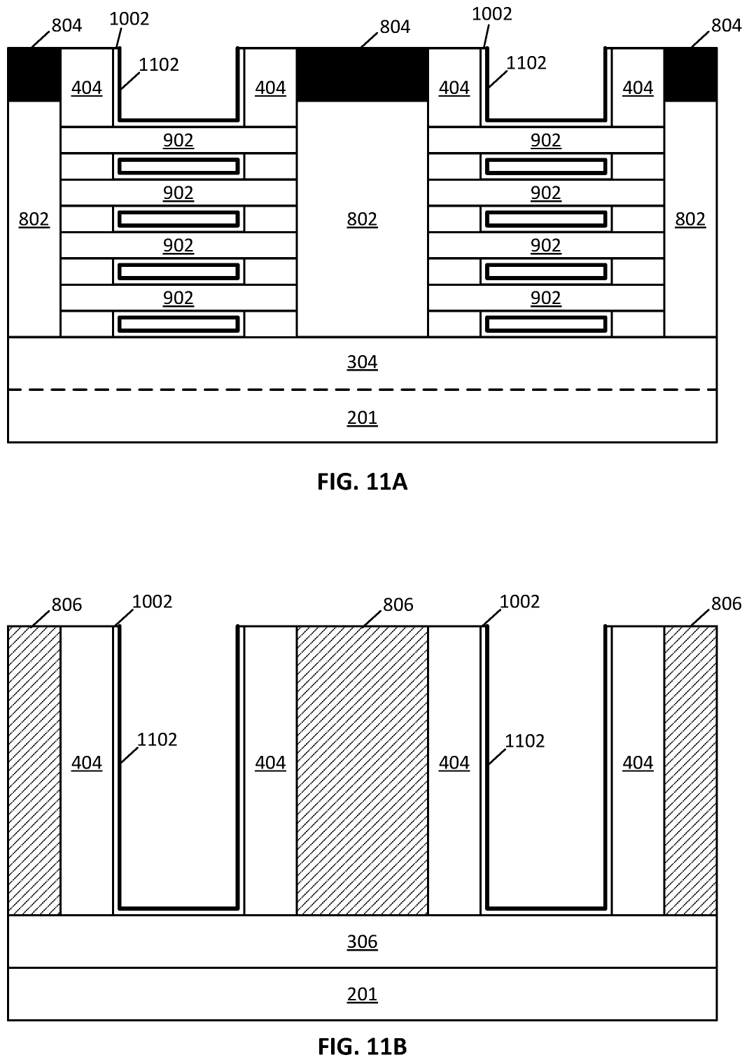

FIGS. 11A and 11B depict cross-section views of the structure shown in FIGS. 10A and 10B, respectively, following the formation of a material layer 1102 over all surfaces of gate dielectric 1002 within the gate trenches, according to some embodiments. Material layer 1102 includes molybdenum, such as molybdenum nitride (MoN), according to some embodiments. Material layer 1102 may be deposited using ALD with molybdenum and ammonia (NH₃) precursors at a temperature between about 380° C. and about 390° C. In some examples, material layer 1102 has a thickness between about 1 nm to 2 nm (e.g., 12 Å and about 16 Å). According to some embodiments, the deposition conditions used to form material layer 1102 do not damage the underlying gate dielectric 1002.

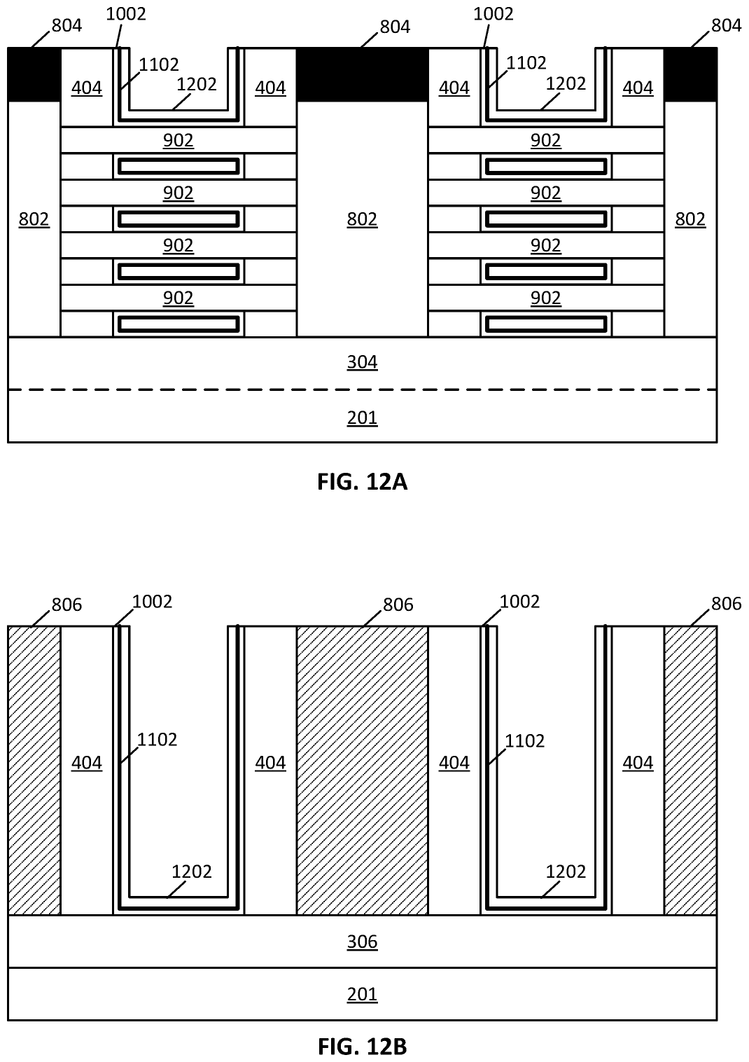

FIGS. 12A and 12B depict cross-section views of the structure shown in FIGS. 11A and 11B, respectively, following the formation of a protection layer 1202 over material layer 1102, according to some embodiments. Protection layer 1202 may include, for example, amorphous silicon or amorphous silicon germanium and may be provided to protect gate dielectric 1002 during an anneal process. Following the formation of protection layer 1202, an annealing procedure is performed to improve the quality of gate dielectric 1002. The temperature and duration of the anneal can vary from one example to the next, but in some cases is in the range of about 550° C. to about 650° C. for about 30 seconds to about 90 seconds.

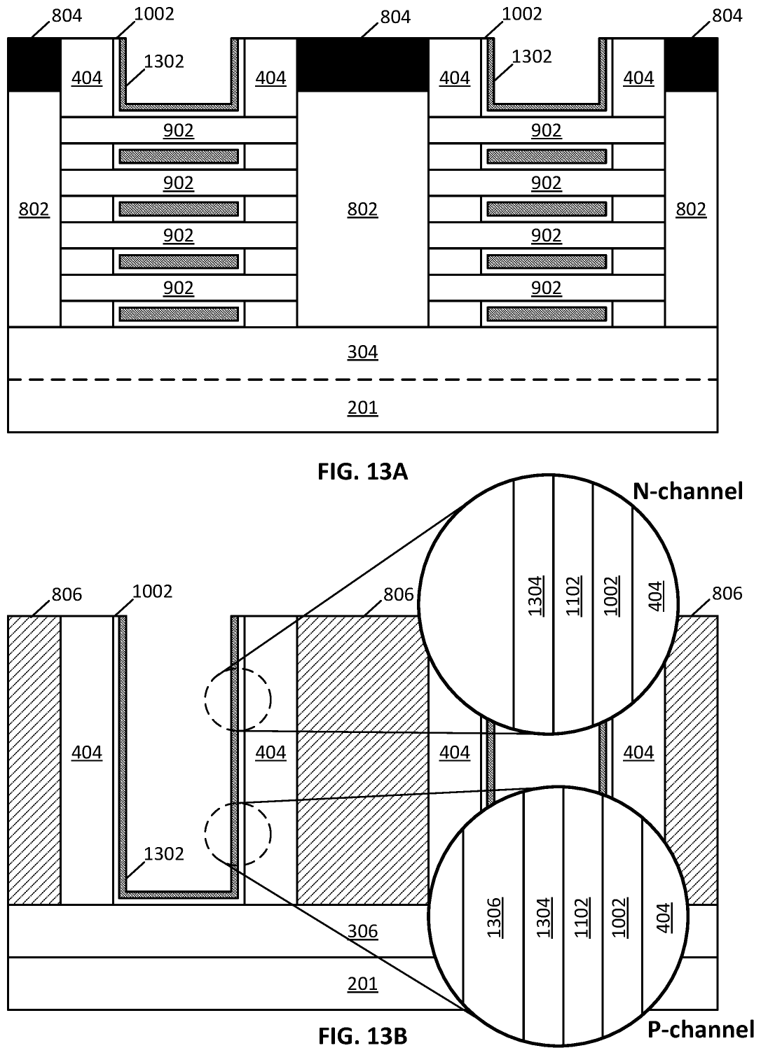

FIGS. 13A and 13B depict cross-section views of the structure shown in FIGS. 12A and 12B, respectively, following the formation of one or more additional conductive layers to form workfunction layers 1302 over gate dielectric 1002, according to some embodiments. Following the annealing process, protection layer 1202 may be removed and one or more additional conductive layers (e.g., one or more metal layers) may be formed over material layer 1102 to provide a stack of workfunction layers 1302. In some embodiments, workfunction layers 1302 fill the area between adjacent nanoribbons 902. Workfunction layers 1302 may be deposited using electroplating, electroless plating, CVD, PECVD, ALD, or PVD, to name a few examples.

The type and thicknesses of the different workfunction layers 1302 depends on the type of transistor (n or p type) as well as the desired threshold voltage of the transistor. For example, an n-channel transistor may have workfunction layers 1302 that include material layer 1102 directly on gate dielectric 1002 and a first workfunction layer 1304 on material layer 1102, as illustrated in the upper magnified portion of FIG. 13B. First workfunction layer 1304 may include, for instance, tantalum nitride. In another example, a p-channel transistor may have workfunction layers 1302 that include material layer 1102 directly on gate dielectric 1002, first workfunction layer 1304 on material layer 1102, and a second workfunction layer 1306 on first workfunction layer 1304, as illustrated in the lower magnified portion of FIG. 13B. Second workfunction layer 1306 may include, for example, titanium nitride. Other workfunction materials may also be used for each of first workfunction layer 1304 and second workfunction layer 1306. In some examples, an additional workfunction metal layer that includes aluminum-doped titanium carbide (TiAlC) is provided within workfunction layers 1302. According to some embodiments, the thickness of second workfunction layer 1306 may be used to adjust the threshold voltage of the p-channel transistor. For example, the threshold voltage of the p-channel transistor generally decreases as the thickness of second workfunction layer 1306 increases.

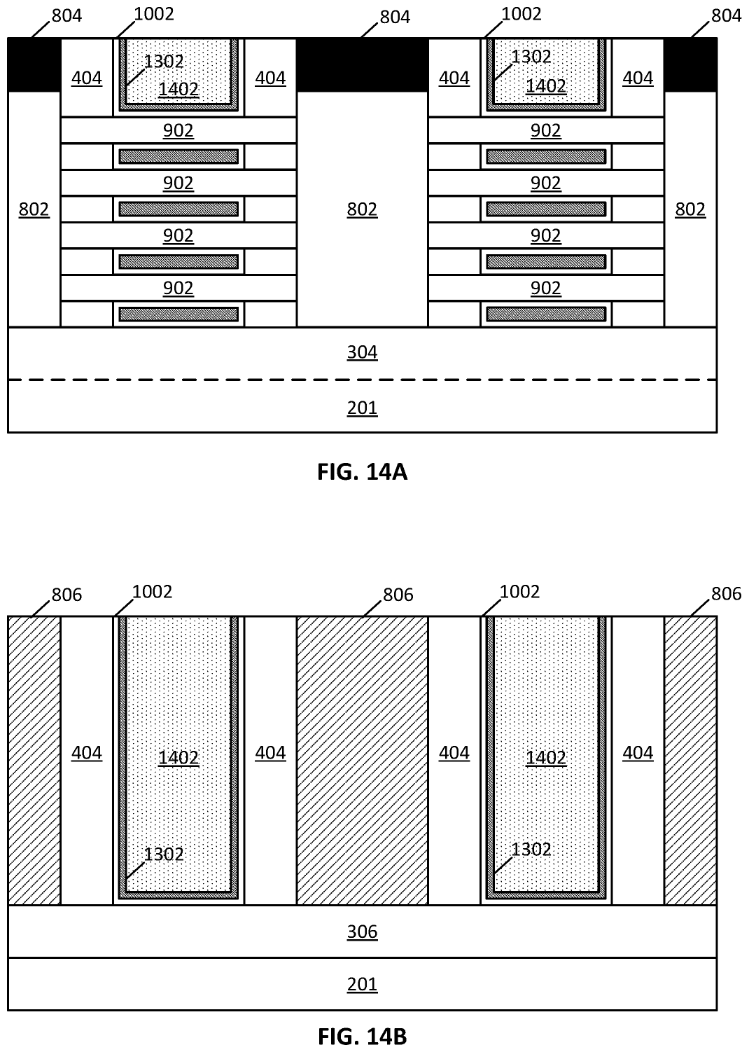

FIGS. 14A and 14B depict cross-section views of the structure shown in FIGS. 13A and 13B, respectively, following the formation of a conductive fill 1402 within a remaining volume of the gate trenches, according to some embodiments. Conductive fill 1402 may include any suitable conductive metal material, such as tungsten, cobalt, or ruthenium. According to some embodiments, conductive fill 1402 also includes one or more conductive adhesion layers to promote better adhesion to the underlying workfunction layers 1302. An example adhesion layer includes titanium nitride. Conductive fill 1402 and workfunction layers 1302 together make up a gate electrode provided on gate dielectric 1002, according to some embodiments. Other examples may not include any conductive fill 1402, where workfunction layers 1302 consume the entire space that remains after deposition of either first workfunction layer 1304 or second workfunction layer 1306.

FIGS. 15A and 15B depict cross-section views of the structure shown in FIGS. 14A and 14B, respectively, following the formation of a gate cap 1502, according to some embodiments. Top portions of the gate electrode may be recessed using any suitable metal etch process with the recessed areas being filled with a dielectric material to form gate cap 1502. Accordingly, gate cap 1502 may be any suitable dielectric material, such as silicon nitride. In some examples, gate cap 1502 includes the same dielectric material as spacer structures 404. Other examples may not include gate cap 1502.

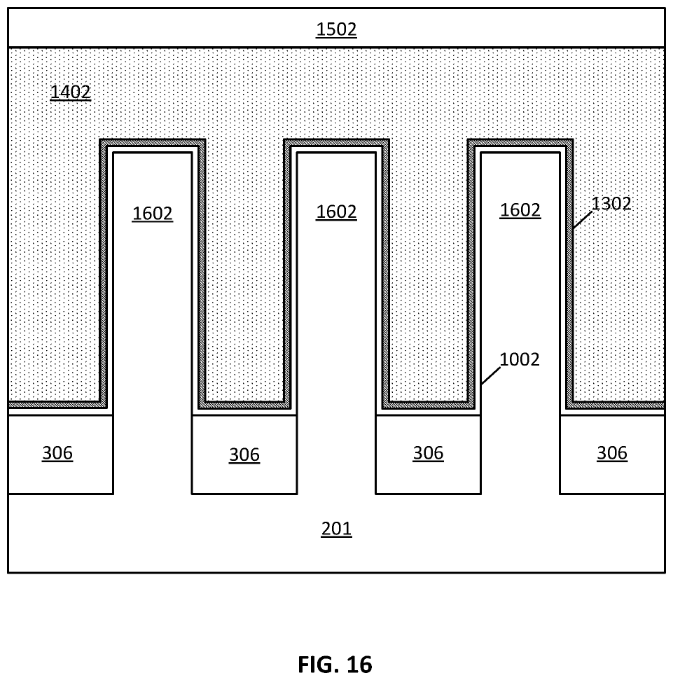

FIG. 16 illustrates another example integrated circuit having a finFET architecture as opposed to a GAA architecture. Accordingly, the semiconductor regions extending between source and drain regions are in the shape of fins 1602 extending above substrate 201. The cross-section of FIG. 16 is taken across the gate trench (along the second direction) through different fins 1602. The same procedures described above for the GAA architecture may be used in the finFET architecture to form the gate structure having gate dielectric 1002, workfunction layers 1302, and conductive fill 1402 on fins 1602. Workfunction layers 1302 may include different metal layers as discussed above depending on whether fins 1602 are part of n-channel or p-channel devices. But in either case, workfunction layers 1302 include a layer having molybdenum.

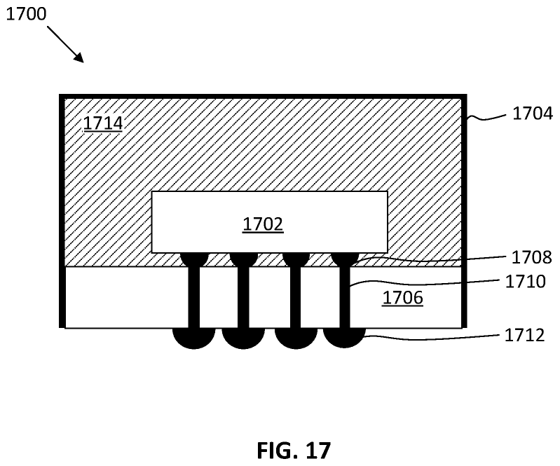

FIG. 17 illustrates an example embodiment of a chip package 1700, in accordance with an embodiment of the present disclosure. As can be seen, chip package 1700 includes one or more dies 1702. One or more dies 1702 may include at least one integrated circuit having semiconductor devices, such as any of the semiconductor devices disclosed herein. One or more dies 1702 may include any other circuitry used to interface with other devices formed on the dies, or other devices connected to chip package 1700, in some example configurations.

As can be further seen, chip package 1700 includes a housing 1704 that is bonded to a package substrate 1706. The housing 1704 may be any standard or proprietary housing, and may provide, for example, electromagnetic shielding and environmental protection for the components of chip package 1700. The one or more dies 1702 may be conductively coupled to a package substrate 1706 using connections 1708, which may be implemented with any number of standard or proprietary connection mechanisms, such as solder bumps, ball grid array (BGA), pins, or wire bonds, to name a few examples. Package substrate 1706 may be any standard or proprietary package substrate, but in some cases includes a dielectric material having conductive pathways (e.g., including conductive vias and lines) extending through the dielectric material between the faces of package substrate 1706, or between different locations on each face. In some embodiments, package substrate 1706 may have a thickness less than 1 millimeter (e.g., between 0.1 millimeters and 0.5 millimeters), although any number of package geometries can be used. Additional conductive contacts 1712 may be disposed at an opposite face of package substrate 1706 for conductively contacting, for instance, a printed circuit board (PCB). One or more vias 1710 extend through a thickness of package substrate 1706 to provide conductive pathways between one or more of connections 1708 to one or more of contacts 1712. Vias 1710 are illustrated as single straight columns through package substrate 1706 for ease of illustration, although other configurations can be used (e.g., damascene, dual damascene, through-silicon via, or an interconnect structure that meanders through the thickness of substrate 1706 to contact one or more intermediate locations therein). In still other embodiments, vias 1710 are fabricated by multiple smaller stacked vias, or are staggered at different locations across package substrate 1706. In the illustrated embodiment, contacts 1712 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 1712, to inhibit shorting.

In some embodiments, a mold material 1714 may be disposed around the one or more dies 1702 included within housing 1704 (e.g., between dies 1702 and package substrate 1706 as an underfill material, as well as between dies 1702 and housing 1704 as an overfill material). Although the dimensions and qualities of the mold material 1714 can vary from one embodiment to the next, in some embodiments, a thickness of mold material 1714 is less than 1 millimeter. Example materials that may be used for mold material 1714 include epoxy mold materials, as suitable. In some cases, the mold material 1714 is thermally conductive, in addition to being electrically insulating.

### Methodology

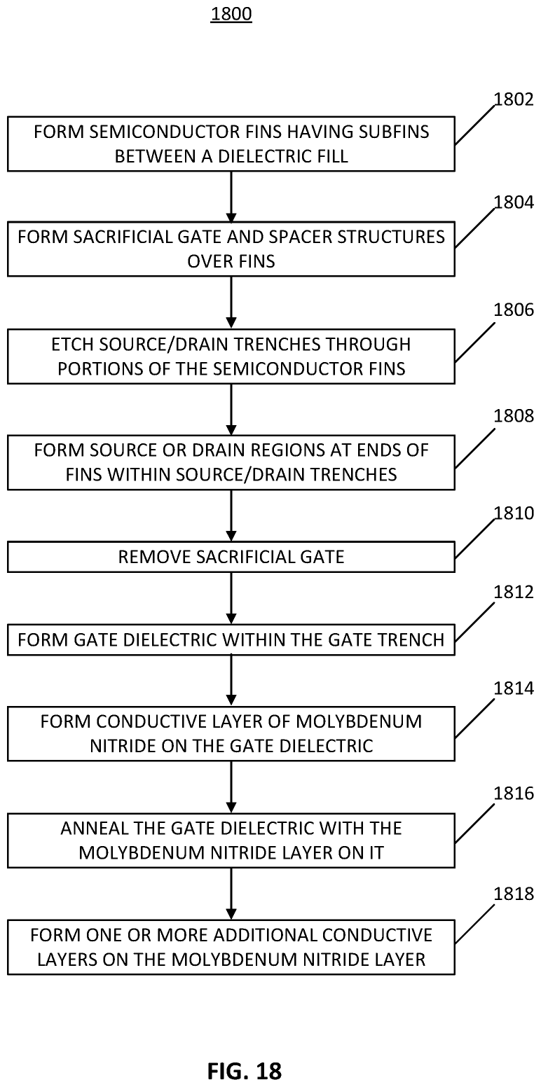

FIG. 18 is a flow chart of a method 1800 for forming at least a portion of an integrated circuit, according to an embodiment. Various operations of method 1800 may be illustrated in FIGS. 2A-15A and 2B-15B. However, the correlation of the various operations of method 1800 to the specific components illustrated in the aforementioned figures is not intended to imply any structural and/or use limitations. Rather, the aforementioned figures provide one example embodiment of method 1800. Other operations may be performed before, during, or after any of the operations of method 1800. For example, method 1800 does not explicitly describe various standard processes that are usually performed to form transistor structures. Some of the operations of method 1800 may be performed in a different order than the illustrated order.

Method 1800 begins with operation 1802 where a plurality of parallel semiconductor fins are formed, according to some embodiments. The semiconductor material in the fins may be formed from a substrate such that the fins are an integral part of the substrate (e.g., etched from a bulk silicon substrate). Alternatively, the fins can be formed of material deposited onto an underlying substrate. In one such example case, a blanket layer of SiGe can be deposited onto a silicon substrate, and then patterned and etched to form a plurality of SiGe fins extending from that substrate. In another such example, non-native fins can be formed in a so-called aspect ratio trapping based process, where native fins are etched away so as to leave fin-shaped trenches which can then be filled with an alternative semiconductor material (e.g., group IV or III-V material). In still other embodiments, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. Again, the alternating layers can be blanket deposited and then etched into fins, or deposited into fin-shaped trenches, according to some examples. The fins may also include a cap structure over each fin that is used to define the locations of the fins during, for example, an RIE process. The cap structure may be a dielectric material, such as silicon nitride.

According to some embodiments, a dielectric fill is formed around subfin portions of the one or more fins. In some embodiments, the dielectric fill extends between each pair of adjacent parallel fins and runs lengthwise in the same direction as the fins. In some embodiments, the anisotropic etching process that forms the fins also etches into a portion of the substrate and the dielectric fill may be formed within the recessed portions of the substrate. Accordingly, the dielectric fill acts as shallow trench isolation (STI) between adjacent fins. The dielectric fill may be any suitable dielectric material, such as silicon dioxide. Lower portions of the fins adjacent to the dielectric fill may be identified as the subfins.

Method 1800 continues with operation 1804 where sacrificial gates are formed over the fins. The sacrificial gates may be patterned using gate masking layers in strips that run orthogonally over the fins and parallel to one another (e.g., forming a cross-hatch pattern). The gate masking layers may be any suitable hard mask material, such as CHM or silicon nitride. The sacrificial gates themselves may be formed from any suitable material that can be selectively removed at a later time without damaging the semiconductor material of the fins. In one example, the sacrificial gates include polysilicon.

According to some embodiments, spacer structures are also formed on sidewalls of at least the sacrificial gates. The spacer structures may be deposited and then etched back such that the spacer structures remain mostly only on sidewalls of any exposed structures. In some cases, spacer structures may also be formed along sidewalls of the exposed fins running orthogonally between the strips of sacrificial gates. According to some embodiments, the spacer structures may be any suitable dielectric material, such as silicon nitride or silicon oxynitride.

Method 1800 continues with operation 1806 where exposed portions of the fins are removed to form source/drain trenches. Any exposed portions of the fins not covered by the sacrificial gates or spacer structures may be removed using any anisotropic etching process, such as reactive ion etching (RIE). Sacrificial layers of the fins may be recessed (e.g., via isotropic etch process) followed by deposition of internal spacers (e.g., silicon nitride), as described above.

Method 1800 continues with operation 1808 where source or drain regions are formed at opposite ends of the fins within the source/drain trenches. The source or drain regions may be formed in the areas that had been previously occupied by the exposed fins between the spacer structures. According to some embodiments, the source or drain regions are epitaxially grown from the exposed semiconductor material of the fins (or nanoribbons, nanowires or nanosheets, as the case may be) along the exterior walls of the spacer structures. In some example embodiments, the source or drain regions are NMOS source or drain regions (e.g., epitaxial silicon with n-type dopants) or PMOS source or drain regions (e.g., epitaxial SiGe with p-type dopants). A dielectric fill may be formed between and over the source or drain regions along a given source/drain trench. The dielectric fill may be any suitable dielectric material, such as silicon dioxide. In some examples, the dielectric fill extends over the source or drain regions up to and planar with a top surface of the spacer structures. The dielectric fill also acts as an electrical insulator between adjacent source or drain regions, although some adjacent source or drain regions may have merged together during their growth.

Method 1800 continues with operation 1810 where the sacrificial gate is removed. According to some embodiments, the sacrificial gate may be removed along with any sacrificial layers within the exposed fins between the spacer structures (in the case of GAA structures). The sacrificial gate and/or sacrificial layers may be removed using any suitable isotropic etching process.

Method 1800 continues with operation 1812 where a gate dielectric is formed within the gate trench (e.g., region previously occupied by the sacrificial gate). The gate dielectric may include any number of dielectric layers deposited using an oxidation process and/or a conformal deposition process, such as ALD. The gate dielectric may include at least one high-k dielectric material layer, such as a layer having hafnium oxide or aluminum oxide.

Method 1800 continues with operation 1814, where a conductive layer that includes molybdenum is formed on the gate dielectric. According to some embodiments, the conductive layer includes molybdenum nitride and may be deposited using ALD with molybdenum and ammonia (NH₃) precursors at a temperature between about 380° C. and about 390° C. In some examples, the conductive layer with molybdenum nitride has a thickness between about 12 Å and about 16 Å. The precursors and temperature used during the formation of the molybdenum nitride layer do not cause any appreciable damage to the gate dielectric. In some embodiments, a protective layer is deposited over the conductive layer including molybdenum. The protective layer may include amorphous silicon, or any other similar amorphous semiconductor material.

Method 1800 continues with operation 1816, where an annealing process is performed with the molybdenum nitride layer on the gate dielectric. The anneal may be performed to strengthen the gate dielectric and improve its electrical characteristics. For example, the annealing may reduce charge traps within the gate dielectric. The temperature and duration of the anneal can vary from one example to the next, but in some cases is in the range of about 550° C. to 650° C. for about 30 seconds to 90 seconds. Following the annealing process, the protective layer may be removed, if it is present.

Method 1800 continues with operation 1818, where one or more additional conductive layers are formed over the molybdenum-containing layer to complete the formation of the gate electrode on the gate dielectric. According to some embodiments, the one or more additional conductive layers include metal workfunction layers and a metal fill on the metal workfunction layers. The metal workfunction layers may be different depending on whether the transistor is to be an n-channel device or a p-channel device. The metal fill may be any suitable conductive material, such as tungsten. In some examples, the metal workfunction layers include at least one layer of tantalum nitride and at least one layer of titanium nitride for p-channel devices and at least one layer of tantalum nitride for n-channel devices. In some examples, the metal workfunction layers also include a layer of TiAlC.

In some embodiments, operation 1818 includes the removal of the molybdenum-containing layer prior to forming the one or more additional conductive layers. Some n-channel devices (e.g., those with a relatively low threshold voltage) may not use the molybdenum-containing layer as one of its workfunction layers. According to some embodiments, the n-channel devices without the molybdenum-containing layer may instead include a workfunction layer of titanium nitride. The n-channel devices having the molybdenum-containing layer removed still benefit from an improved gate dielectric due to the presence of the molybdenum-containing layer during the annealing process in operation 1816.

### Example System

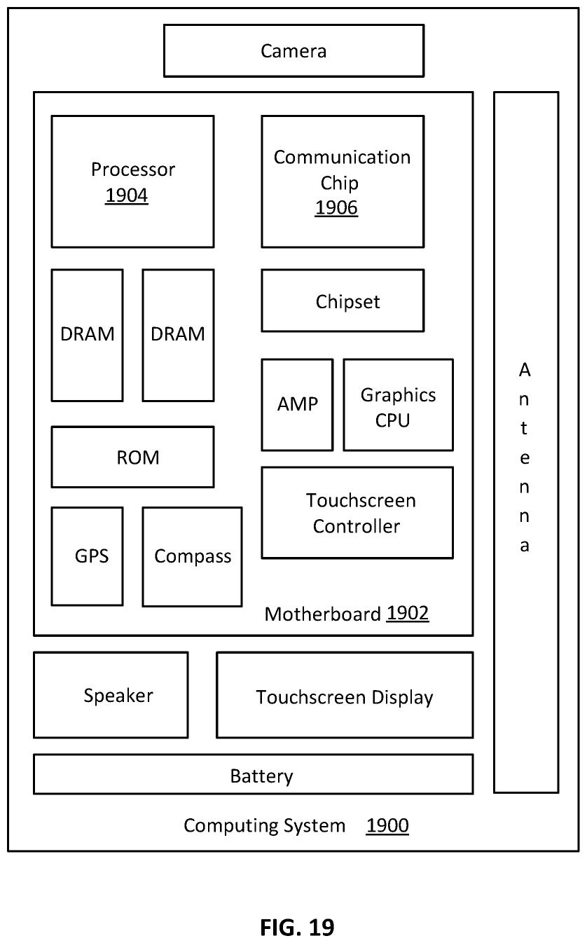

FIG. 19 is an example computing system implemented with one or more of the integrated circuit structures as disclosed herein, in accordance with some embodiments of the present disclosure. As can be seen, the computing system 1900 houses a motherboard 1902. The motherboard 1902 may include a number of components, including, but not limited to, a processor 1904 and at least one communication chip 1906, each of which can be physically and electrically coupled to the motherboard 1902, or otherwise integrated therein. As will be appreciated, the motherboard 1902 may be, for example, any printed circuit board (PCB), whether a main board, a daughterboard mounted on a main board, or the only board of system 1900, etc.

Depending on its applications, computing system 1900 may include one or more other components that may or may not be physically and electrically coupled to the motherboard 1902. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1900 may include one or more integrated circuit structures or devices configured in accordance with an example embodiment (e.g., a module including an integrated circuit device on a substrate, the substrate having one or more semiconductor devices that include a gate structure which includes at least one layer having molybdenum, as variously provided herein). In some embodiments, multiple functions can be integrated into one or more chips (e.g., for instance, note that the communication chip 1906 can be part of or otherwise integrated into the processor 1904).

The communication chip 1906 enables wireless communications for the transfer of data to and from the computing system 1900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1906 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1900 may include a plurality of communication chips 1906. For instance, a first communication chip 1906 may be dedicated to shorter range wireless communications such as Wi-Fi and Bluetooth and a second communication chip 1906 may be dedicated to longer range wireless communications such as GPS, EDGE, GPRS, CDMA, WiMAX, LTE, Ev-DO, and others.

The processor 1904 of the computing system 1900 includes an integrated circuit die packaged within the processor 1904. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 1906 also may include an integrated circuit die packaged within the communication chip 1906. In accordance with some such example embodiments, the integrated circuit die of the communication chip includes one or more semiconductor devices as variously described herein. As will be appreciated in light of this disclosure, note that multi-standard wireless capability may be integrated directly into the processor 1904 (e.g., where functionality of any chips 1906 is integrated into processor 1904, rather than having separate communication chips). Further note that processor 1904 may be a chip set having such wireless capability. In short, any number of processor 1904 and/or communication chips 1906 can be used. Likewise, any one chip or chip set can have multiple functions integrated therein.

In various implementations, the computing system 1900 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 1900 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is a method of forming an integrated circuit that includes forming a fin comprising one or more semiconductor layers, the fin extending in a first direction over a substrate; forming a sacrificial gate, the sacrificial gate extending in a second direction over the fin, the second direction being different from the first direction; removing an exposed portion of the fin adjacent to the sacrificial gate to form a recess through the fin; forming a source or drain region from ends of the one or more semiconductor layers and within the recess; removing the sacrificial gate from around the fin; forming one or more dielectric layers on the one or more semiconductor layers of the fin; forming a conductive layer on the one or more dielectric layers, wherein the conductive layer comprises molybdenum and nitrogen; after forming the conductive layer, annealing the one or more dielectric layers; and forming one or more additional conductive layers over the conductive layer.

Example 2 includes the method of Example 1, wherein forming the conductive layer comprises forming the conductive layer using an atomic layer deposition (ALD) process.

Example 3 includes the method of Example 2, wherein the conductive layer comprises molybdenum and nitrogen, and the ALD process uses molybdenum with an ammonia (NH₃) precursor gas.

Example 4 includes the method of any one of Examples 1-3, wherein forming the conductive layer comprises forming the conductive layer to a thickness between about 12 Å and about 16 Å.

Example 5 includes the method of any one of Examples 1-4, wherein forming the conductive layer comprises forming the conductive layer at a temperature of less than 400° C.

Example 6 includes the method of any one of Examples 1-5, wherein the one or more dielectric layers comprises at least one layer having a high-k dielectric material.

Example 7 includes the method of Example 6, wherein the high-k dielectric material comprises hafnium and oxygen.

Example 8 includes the method of any one of Examples 1-7, wherein forming the one or more additional conductive layers comprises forming at least one additional conductive layer comprising nitrogen and one of tantalum or titanium.

Example 9 includes the method of any one of Examples 1-8, wherein forming the sacrificial gate includes forming spacers on sidewalls of the sacrificial gate, and removing the sacrificial gate includes removing the sacrificial gate between the spacers, so as to expose the one or more semiconductor layers between the spacers.

Example 10 includes the method of any one of Examples 1-9, further comprising removing the conductive layer and the one or more additional conductive layers to expose the one or more dielectric layers.

Example 11 includes the method of Example 10, further comprising forming another conductive layer comprising titanium and nitrogen on the one or more dielectric layers.

Example 12 is an integrated circuit that includes a semiconductor region extending from a source or drain region in a first direction, and a gate structure extending over the semiconductor region in a second direction different from the first direction. The gate structure includes one or more dielectric layers on the semiconductor region and one or more conductive layers on the one or more dielectric layers. The one or more conductive layers includes a conductive layer comprising molybdenum and nitrogen. The source or drain region includes silicon, germanium, or silicon germanium (SiGe) doped with n-type dopants.

Example 13 includes the integrated circuit of Example 12, wherein the conductive layer is directly on the one or more dielectric layers.

Example 14 includes the integrated circuit of Example 12 or 13, wherein the conductive layer further comprises nitrogen and has a thickness between about 12 Å and about 16 Å.

Example 15 includes the integrated circuit of any one of Examples 12-14, wherein the one or more dielectric layers comprises at least one layer having a high-k dielectric material.

Example 16 includes the integrated circuit of Example 15, wherein the high-k dielectric material comprises hafnium and oxygen.

Example 17 includes the integrated circuit of any one of Examples 12-16, wherein the semiconductor region comprises one or more semiconductor nanoribbons.

Example 18 includes the integrated circuit of Example 17, wherein the one or more semiconductor nanoribbons comprises germanium, silicon, or any combination thereof.

Example 19 includes the integrated circuit of any one of Examples 12-18, wherein the conductive layer is a first conductive layer, and the one or more conductive layers comprises a second conductive layer on the first conductive layer that comprises nitrogen and one of tantalum or titanium.

Example 20 is a printed circuit board comprising the integrated circuit of any one of Examples 12-19.

Example 21 is an electronic device that includes a chip package having one or more dies. At least one of the one or more dies includes a semiconductor device having a semiconductor region extending from a source or drain region in a first direction and a gate structure extending over the semiconductor region in a second direction different from the first direction. The gate structure includes one or more dielectric layers on the semiconductor region and one or more conductive layers on the one or more dielectric layers. The one or more conductive layers includes a conductive layer comprising molybdenum and nitrogen. The source or drain region includes silicon, germanium, or SiGe doped with n-type dopants.

Example 22 includes the electronic device of Example 21, wherein the conductive layer is directly on the one or more dielectric layers.

Example 23 includes the electronic device of Example 21 or 22, wherein the conductive layer has a thickness between about 12 Å and about 16 Å.

Example 24 includes the electronic device of any one of Examples 21-23, wherein the one or more dielectric layers comprises at least one layer having a high-k dielectric material.

Example 25 includes the electronic device of Example 24, wherein the high-k dielectric material comprises hafnium and oxygen.

Example 26 includes the electronic device of any one of Examples 21-25, wherein the semiconductor region comprises one or more semiconductor nanoribbons.

Example 27 includes the electronic device of Example 26, wherein the one or more semiconductor nanoribbons comprises germanium, silicon, or any combination thereof.

Example 28 includes the electronic device of any one of Examples 21-27, wherein the conductive layer is a first conductive layer, and the one or more conductive layers comprises a second conductive layer on the first conductive layer that comprises tantalum and nitrogen.

Example 29 includes the electronic device of any one of Examples 21-28, wherein the semiconductor device is first semiconductor device, the semiconductor region is a first semiconductor region, the source or drain region is a first source or drain region, the gate structure is a first gate structure, the one or more dielectric layers are first one or more dielectric layers, and the one or more conductive layers are first one or more conductive layers. The at least one of the one or more dies further includes a second semiconductor device having a second semiconductor region extending from a second source or drain region in the first direction and a second gate structure extending over the second semiconductor region in the second direction. The second gate structure includes one or more second dielectric layers on the second semiconductor region and one or more second conductive layers on the one or more second dielectric layers. The one or more second conductive layers includes a conductive layer comprising molybdenum and nitrogen. The second source or drain region includes silicon, germanium, or SiGe doped with p-type dopants.

Example 30 includes the electronic device of any one of Examples 21-29, further comprising a printed circuit board (PCB), wherein the chip package is attached to the PCB.

Example 31 is a method of forming an integrated circuit that includes forming a fin comprising one or more semiconductor layers, the fin extending in a first direction over a substrate; forming a sacrificial gate, the sacrificial gate extending in a second direction over the fin, the second direction being different from the first direction; removing an exposed portion of the fin adjacent to the sacrificial gate to form a recess through the fin; forming a source or drain region that includes silicon doped with n-type dopants from ends of the one or more semiconductor layers and within the recess; removing the sacrificial gate from around the fin; forming one or more dielectric layers on the one or more semiconductor layers of the fin; forming a conductive layer on the one or more dielectric layers, wherein the conductive layer comprises molybdenum and nitrogen; and forming one or more additional conductive layers over the conductive layer.

Example 32 includes the method of Example 31, further comprising annealing the one or more dielectric layers after forming the conductive layer.

Example 33 includes the method of Example 31 or 32, wherein forming the conductive layer comprises forming the conductive layer at a temperature of less than 400° C.

Example 34 includes the method of any one of Examples 31-33, further comprising removing the conductive layer and the one or more additional conductive layers to expose the one or more dielectric layers.

Example 35 includes the method of Example 34, further comprising forming another conductive layer comprising titanium and nitrogen on the one or more dielectric layers.

Example 36 includes the method of any one of Examples 1-11, wherein the annealing comprises annealing the one or more dielectric layers at about 550° C. to about 650° C. for about 30 seconds to about 90 seconds.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. A method of forming an integrated circuit, comprising:
forming a fin comprising one or more semiconductor layers, the fin extending in a first direction;
forming a sacrificial gate, the sacrificial gate extending in a second direction over the fin, the second direction being different from the first direction;
removing an exposed portion of the fin adjacent to the sacrificial gate to form a recess through the fin;
forming a source or drain region from ends of the one or more semiconductor layers and within the recess;
removing the sacrificial gate from around the fin;
forming one or more dielectric layers on the one or more semiconductor layers of the fin;
forming a conductive layer on the one or more dielectric layers, wherein the conductive layer comprises molybdenum;
after forming the conductive layer, annealing the one or more dielectric layers; and
forming one or more additional conductive layers over the conductive layer.

2. The method of claim 1, wherein forming the conductive layer comprises forming the conductive layer using an atomic layer deposition (ALD) process.

3. The method of claim 2, wherein the conductive layer comprises molybdenum and nitrogen, and the ALD process uses molybdenum with an ammonia (NH₃) precursor gas.

4. The method of claim 1, wherein forming the conductive layer comprises forming the conductive layer to a thickness between about 12 Å and about 16 Å.

5. The method of claim 1, wherein forming the conductive layer comprises forming the conductive layer at a temperature of less than 400° C.

6. The method of claim 1, wherein the one or more dielectric layers comprises at least one layer having a high-k dielectric material.

7. The method of claim 1, further comprising removing the conductive layer and the one or more additional conductive layers to expose the one or more dielectric layers.

8. The method of claim 7, further comprising forming another conductive layer comprising titanium and nitrogen on the one or more dielectric layers.

9. The method of claim 1, wherein the annealing comprises annealing the one or more dielectric layers at about 550° C. to about 650° C. for about 30 seconds to about 90 seconds.

10. An integrated circuit comprising:
a semiconductor region extending from a source or drain region in a first direction, wherein the source or drain region comprises silicon doped with n-type dopants; and
a gate structure extending over the semiconductor region in a second direction different from the first direction, wherein the gate structure comprises
one or more dielectric layers on the semiconductor region, and
one or more conductive layers on the one or more dielectric layers, wherein the one or more conductive layers includes a conductive layer comprising molybdenum and nitrogen.

11. The integrated circuit of claim 10, wherein the conductive layer is directly on the one or more dielectric layers.

12. The integrated circuit of claim 10, wherein the conductive layer has a thickness between about 12 Å and about 16 Å.

13. The integrated circuit of claim 10, wherein the one or more dielectric layers comprises at least one layer having a high-k dielectric material.

14. The integrated circuit of claim 10, wherein the conductive layer is a first conductive layer, and the one or more conductive layers comprises a second conductive layer on the first conductive layer that comprises nitrogen and one of tantalum or titanium.

15. The integrated circuit of claim 10, wherein the semiconductor region is a first semiconductor region, the source or drain region is a first source or drain region, the gate structure is a first gate structure, the one or more dielectric layers are first one or more dielectric layers, the one or more conductive layers are first one or more conductive layers, and the at least one of the one or more dies further includes:
a second semiconductor region extending from a second source or drain region in the first direction, wherein the second source or drain region comprises silicon doped with p-type dopants, and
a second gate structure extending over the second semiconductor region in the second direction, wherein the second gate structure comprises
one or more second dielectric layers on the second semiconductor region, and
one or more second conductive layers on the one or more second dielectric layers, wherein the one or more second conductive layers includes a conductive layer comprising molybdenum and nitrogen.

16. A method of forming an integrated circuit, comprising:
forming a fin comprising one or more semiconductor layers, the fin extending in a first direction;
forming a sacrificial gate, the sacrificial gate extending in a second direction over the fin, the second direction being different from the first direction;
removing an exposed portion of the fin adjacent to the sacrificial gate to form a recess through the fin;
forming a source or drain region that comprises silicon doped with n-type dopants from ends of the one or more semiconductor layers and within the recess;
removing the sacrificial gate from around the fin;
forming one or more dielectric layers on the one or more semiconductor layers of the fin;
forming a conductive layer on the one or more dielectric layers, wherein the conductive layer comprises molybdenum; and
forming one or more additional conductive layers over the conductive layer.

17. The method of claim 16, further comprising annealing the one or more dielectric layers after forming the conductive layer.

18. The method of claim 16, wherein forming the conductive layer comprises forming the conductive layer at a temperature of less than 400° C.

19. The method of claim 16, further comprising removing the conductive layer and the one or more additional conductive layers to expose the one or more dielectric layers.

20. The method of claim 19, further comprising forming another conductive layer comprising titanium and nitrogen on the one or more dielectric layers.
